(19) United States
(12) Patent Application Publication
(10) Pub. No.: US 2025/0151192 A1
(43) Pub. Date: May 8, 2025

(54) FLEXIBLE SUBSTRATE

(71) Applicant: Japan Display Inc., Minato-ku, Tokyo (JP)

(72) Inventors: Takumi SANO, Tokyo (JP); Yosuke HYODO, Tokyo (JP)

(73) Assignee: Japan Display Inc., Minato-ku, Tokyo (JP)

(21) Appl. No.: 18/921,366

(22) Filed: Oct. 21, 2024

(30) Foreign Application Priority Data
Oct. 30, 2023 (JP) 2023-185592

(51) Int. Cl. H05K 1/02; H05K 1/18

(52) U.S. Cl. CPC H05K 1/0296; H05K 1/189

(57) ABSTRACT

According to one embodiment, a flexible substrate including, an insulating base including first strip portions, second strip portions, and island-shaped portions each located at an intersection between the first strip portions and the second strip portions, electrical elements overlapping the island-shaped portions, respectively, scanning lines extending while overlapping the first strip portions, respectively, signal lines extending while overlapping the second strip portions, respectively, a first organic insulating film, a second organic insulating film, a stopper layer located between the first and second organic insulating film, and a barrier layer located on the second organic insulating film.

### CROSS-REFERENCE TO RELATED APPLICATIONS

This application is based upon and claims the benefit of priority from Japanese Patent Application No. 2023-185592, filed Oct. 30, 2023, the entire contents of which are incorporated herein by reference.

### FIELD

Embodiments described herein relate generally to a flexible substrate.

### BACKGROUND

In recent years, the use of flexible substrates with flexibility and elasticity has been studied in various fields. For example, such use can be considered that a flexible substrate with electrical elements arrayed in a matrix shape is attached to a curved surface such as of the housing of an electronic device, human body or the like. As electrical elements, various sensors such as touch sensors and temperature sensors, display elements and the like can be applied.

In flexible substrates, it is necessary to take measures to prevent the wiring from being damaged by stress caused by bending or stretching. As such measures, for example, it has been proposed to provide honeycomb-shaped openings in the base that supports the wiring or to shape the wiring into a meandering manner (meander shape).

### BRIEF DESCRIPTION OF THE DRAWINGS

FIG. 1 is a plan view schematically showing a flexible substrate according to an embodiment.

FIG. 2 is a partially enlarged plan view of the flexible substrate shown in FIG. 1.

FIG. 3 is a cross-sectional view of the flexible substrate shown in FIG. 2, taken along the line A-B.

FIG. 4 is a cross-sectional view of the flexible substrate shown in FIG. 2, taken along the line C-D.

FIG. 5 is a plan view showing a barrier layer and a stopper layer.

FIG. 6 is a cross-sectional view of the flexible substrate shown in FIG. 2, taken along the line A-B.

FIG. 7 is a cross-sectional view of the flexible substrate shown in FIG. 2, taken along the line C-D.

FIG. 8 is a plan view showing a stopper layer.

FIG. 9 is a cross-sectional view of the flexible substrate shown in FIG. 8, taken along the line A-B.

FIG. 10 is a cross-sectional view of the flexible substrate shown in FIG. 8, taken along the line C-D.

FIG. 11 is a cross-sectional view of the flexible substrate shown in FIG. 8, taken along the line A-B.

FIG. 12 is a cross-sectional view of the flexible substrate shown in FIG. 8, taken along the line C-D.

FIG. 13 is a cross-sectional view of the flexible substrate shown in FIG. 8, taken along the line A-B.

FIG. 14 is a cross-sectional view of the flexible substrate shown in FIG. 8, taken along the line C-D.

FIG. 15 is a cross-sectional view of the flexible substrate shown in FIG. 8, taken along the line A-B.

FIG. 16 is a cross-sectional view of the flexible substrate shown in FIG. 8, taken along the line C-D.

FIG. 17 is a plan view showing a stopper layer.

### DETAILED DESCRIPTION

In general, according to one embodiment, a flexible substrate comprises an insulating base including a plurality of first strip portions extending along a first direction and aligned along a second direction intersecting the first direction, a plurality of second strip portions extending along the second direction and aligned along the first direction, and a plurality of island-shaped portions each located at an intersection between a respective one of the first strip portions and a respective one of the second strip portions, a plurality of electrical elements overlapping the island-shaped portions, respectively, a plurality of scanning lines extending while overlapping the first strip portions, respectively, a plurality of signal lines extending while overlapping the second strip portions, respectively, a first organic insulating film located on a layer above the scanning lines and the signal lines and overlapping the first strip portions and the second strip portions, a second organic insulating film located on the first organic insulating film, a stopper layer located between the first organic insulating film and the second organic insulating film, and a barrier layer located on the second organic insulating film.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

### First Embodiment

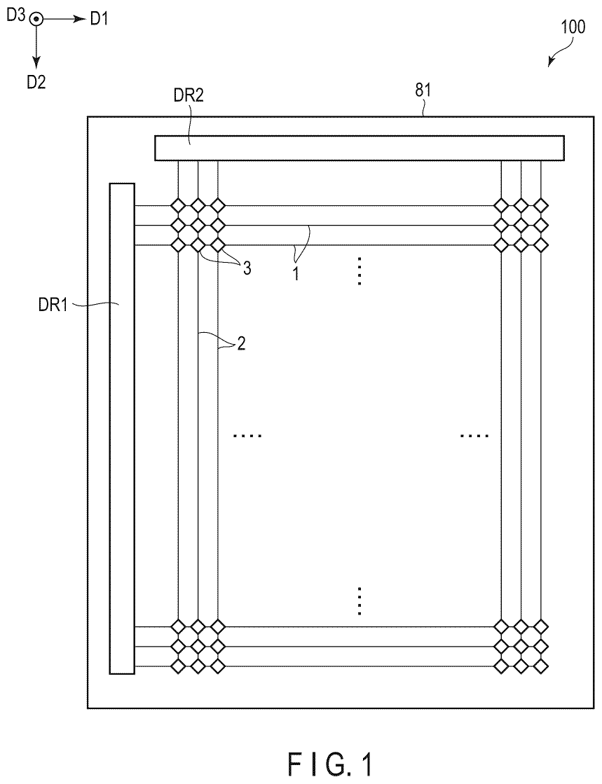

First, a configuration of the first embodiment will be described with reference to FIGS. 1 to 5.

FIG. 1 is a plan view schematically showing a flexible substrate 100 according to the embodiment.

In this embodiment, a first direction D1, a second direction D2 and a third direction D3 are defined as shown in the figure. The first direction D1 and the second direction D2 are parallel to a main surface of the flexible substrate 10 and intersect each other. The third direction D3 is perpendicular to the first direction D1 and the second direction D2, and corresponds to the thickness direction of the flexible substrate 100. The first direction D1 and the second direction D2 intersect normal to each other in this embodiment, but they may intersect at an angle other than normal. In this specification, the direction toward the tip of the arrow indicating the third direction D3 is referred to as “upwards” and the direction from the tip of the arrow to the opposite direction is referred to as “downward”. Further, it is assumed that there is an observation position for observing the flexible substrate 100 on the tip side of the arrow indicating the third direction D3, and viewing from this observation position toward a D1-D2 plane defined by the first direction D1 and the second direction D2 is called a plan view.

As shown in FIG. 1, the flexible substrate 100 includes a plurality of scanning lines 1, a plurality of signal lines 2, a plurality of electrical elements 3, a resin layer 81, a scanning line driver DR1 and a signal line driver DR2. The scanning lines 1, the signal lines 2, the electrical elements 3, the scanning line driver DR1 and the signal line driver DR2 are located on the resin layer 81.

The scanning lines 1 each extend along the first direction D1 and aligned along the second direction D2. The scanning lines 1 are each connected to the scanning line driver DR1. The signal lines 2 each extend along the second direction D2 and aligned along the first direction D1. The signal lines 2 are each connected to the signal line driver DR2. The electrical elements 3 are each located at an intersection between each scanning line 1 and each respective signal line 2 and are electrically connected to the scanning lines 1 and the signal lines 2, respectively.

To the electrical elements 3, scanning signals are supplied via the scanning lines 1, respectively. For example, when the electrical elements 3 are of a type such as sensors which output a signal, the output signal from each electrical element 3 is supplied to the respective signal line 2. Note that the scanning lines 1 and the signal lines 2 are examples of the wiring lines provided in the flexible substrate 100. In addition to the scanning lines 1 and signal lines 2, the flexible substrate 100 may include other types of wiring lines, such as power lines that supply power to the electrical elements 3.

The scanning line driver DR1 functions as a supply source that supplies scanning signals to each of the scanning lines 1. Meanwhile, the signal line driver DR2 functions as a supply source that supplies drive signals to each of the signal lines 2, or as a signal processor that processes the output signals output to each of the signal lines 2.

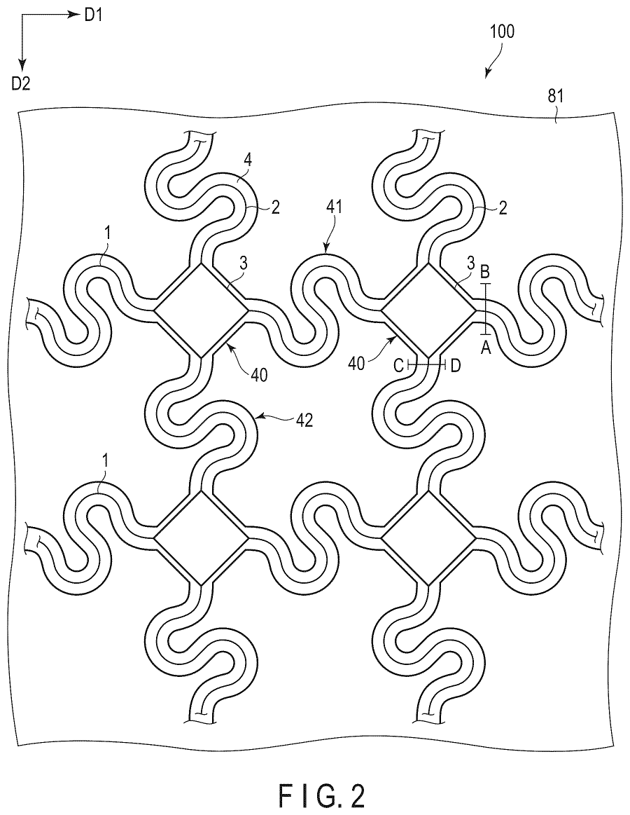

FIG. 2 is a partially enlarged plan view of the flexible substrate 100 shown in FIG. 1.

As shown in FIG. 2, the flexible substrate 100 comprises, in addition to the above, an insulating base 4 that supports the scanning lines 1 and the signal lines 2. The insulating base 4 has elasticity and flexibility. The insulating base 4 is formed using polyimide, for example, but the material is not limited to that of this example.

The insulating base 4 includes a plurality of island-shaped portions 40, a plurality of first strip portions 41 and a plurality of second strip portions 42 which are integrated respectively with the island-shaped portions 40. The insulating base 4 is formed into a net-like shape. The plurality of island-shaped portions 40 are arranged to be spaced apart from each other in a matrix along the first direction D1 and the second direction D2. The island-shaped portions 40 are located at the respective intersections of the first strip portions 41 and the second strip portions 42. Each of the island-shaped portions 40 is formed into a quadrangular shape, for example, in plan view. Note that the island-shaped portions 40 may be formed in some other polygonal shape or in circular or elliptical shapes.

The first strip portions 41 each extend approximately along the first direction Dl and are aligned along the second direction D2. The first strip portions 41 connect a plurality of island-shaped portions 40 aligned along the first direction D1. The second strip portions 42 each extend approximately along the second direction D2 and are aligned along the first direction D1. The second strip portions 42 connect a plurality of island-shaped portions 40 aligned along the second direction D2. The first strip portions 41 and the second strip portions 42 are each formed to be wavy in plan view. In other words, the first strip portions 41 and the second strip portions 42 are formed in a meander shape in plan view.

The scanning lines 1 each extend while overlapping the first strip portions 41, respectively. The signal lines 2 each extend with while overlapping the second strip portions 42, respectively. That is, the scanning lines 1 and the signal lines 2 are all formed in a meander shape.

The electrical elements 3 are provided to overlap the island-shaped portions 40, respectively. For example, the electrical elements 3 are sensors, semiconductor devices, actuators or the like. For example, as sensors, optical sensors that receive visible or near-infrared light, temperature sensors, pressure sensors, touch sensors or the like can be applied. For example, as semiconductor elements, light emitting elements, light receiving elements, diodes, transistors or the like can be applied. When the electrical elements 3 are each a light emitting element, a flexible display with flexibility and elasticity can be realized. As light emitting elements, for example, light emitting diode having a size of around 100 μm, such as mini LEDs or micro LEDs, or organic electroluminescent element can be applied. When the electrical elements 3 are each an actuator, for example, piezoelectric elements can be applied. Note that the electrical elements 3 are not limited to those exemplified here, but other elements with various functions can as well be applied. The electrical elements 3 may be capacitors, resistors, or the like. The arrangement and shape of the electrical elements 3 are not limited to those shown in the example of FIG. 2.

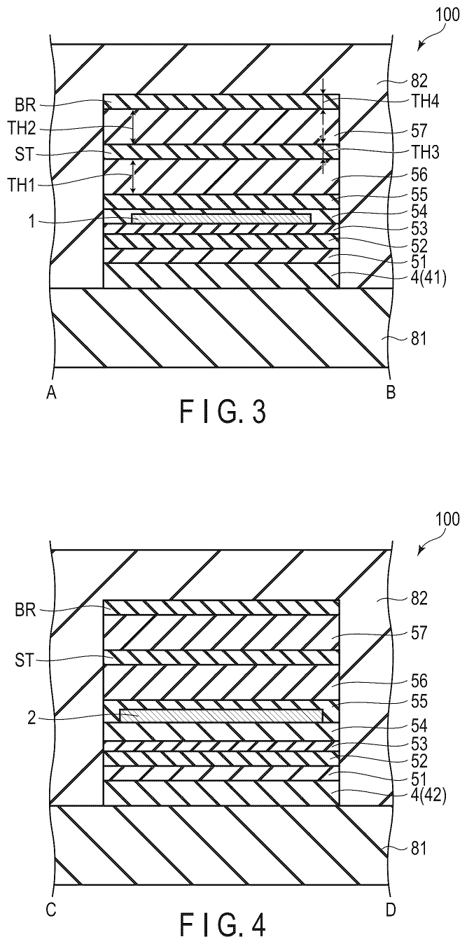

FIG. 3 is a cross-sectional view of the flexible substrate 100 taken along the line A-B shown in FIG. 2.

As shown in FIG. 3, the flexible substrate 100 further comprises insulating films 51 to 57, a stopper layer ST, a barrier layer BR, and a resin layer 82.

The insulating substrate 4 is located on the resin layer 81. The insulating film 51 is located on the insulating substrate 4. The insulating film 52 is located on the insulating film 51. The insulating film 53 is located on the insulating film 52. The scanning lines 1 are located on the insulating film 53. The insulating film 54 is located on the insulating film 53 so as to cover the scanning lines 1. The insulating film 55 is located on the insulating film 54.

All of the insulating films 51 to 55 are inorganic insulating films each formed of an inorganic insulating material such as silicon oxide (SiO), silicon nitride (SiN), silicon oxynitride (SiON) or the like.

The insulating film (first organic insulating film) 56 is located on the insulating film 55. The insulating film 56 is located above the scanning lines 1 and overlaps the first strip portions 41. The stopper layer ST is located on the insulating film 56. The stopper layer ST serves to suppress cracks which may occur above from reaching the scanning lines 1 and signal lines 2. The stopper layer ST is formed from any one of silicon oxide (SiO), silicon nitride (SiN), polysilicon (Poly-Si), aluminum (Al), titanium (Ti), and copper (Cu). The insulating film (second organic insulating film) 57 is located on the insulating film 56 and the stopper layer ST. The stopper layer ST is located between the insulating film 56 and the insulating film 57.

The insulating films 56 and 57 are, for example, organic insulating films each formed of an organic insulating material such as acrylic resin.

The insulating film 56 has a first film thickness of TH1. The insulating film 57 has a second film thickness TH2. The first film thickness TH1 and the second film thickness TH2 are equal to each other. That is, the stopper layer ST is located approximately along the center of the total sum of the thicknesses of the insulating films 56 and 57.

The barrier layer BR is located on the insulating film 57. The barrier layer BR is formed, for example, from any of silicon oxide (SiO), silicon nitride (SiN), polysilicon (Poly-Si), aluminum (Al), titanium (Ti), and copper (Cu). The barrier layer BR may as well be formed of the same material as that of the stopper layer ST. The barrier layer BR serves to inhibit moisture and the like from entering from above the flexible substrate 100.

The barrier layer BR and the stopper layer ST are disposed to overlap the scanning lines 1.

The rigidity of the stopper layer ST is equal to or less than that of the barrier layer BR. For example, when the stopper layer ST is formed from the same material as that of the barrier layer BR, the third film thickness TH3 of the stopper layer ST is equal to or less than the fourth film thickness TH4 of the barrier layer BR. When the stopper layer ST is formed from a material different from that of the barrier layer BR, the elastic modulus of the materials used for the stopper layer ST and barrier layer BR and their respective film thicknesses are adjusted to make the stopper layer ST less rigid than the barrier layer BR. By making the stopper layer ST less rigid than the barrier layer BR, the stopper layer ST can be made less likely to break. Further, the elasticity of the flexible substrate 100 can be improved.

The resin layer 82 covers the insulating substrate 4, the insulating films 51 to 57, the stopper layer ST, and the barrier layer BR. The resin layer 82 is in contact with the resin layer 81.

FIG. 4 is a cross-sectional view showing the flexible substrate 100 taken along the line C-D shown in FIG. 2.

The signal lines 2 are located on the insulating film 54. The insulating film 55 is located one the insulating film 54 so as to cover the signal lines 2. The insulating film 56 is located in a layer above the signal lines 2 and overlaps the second strip portions 42. The barrier layer BR and the stopper layer ST overlap the signal lines 2.

Further, as shown in FIGS. 3 and 4, the scanning lines 1, the insulating film 54, the signal lines 2, and the insulating film 55 are stacked in this order.

According to this embodiment, the stopper layer ST is located between the barrier layer BR and the scanning lines 1. Further, the stopper layer ST is located between the barrier layer BR and the signal lines 2. For example, when the flexible substrate 100 is stretched, a crack may occur from the barrier layer BR. When a crack occurs in the barrier layer BR, and the crack progresses in the film thickness direction, the progressing of the crack can be stopped by the stopper layer ST, thus making it possible to reduce the risk that scanning lines 1 and signal lines 2 may be broken.

Further, the first film thickness TH1 of the insulating film 56 and the second film thickness TH2 of the insulating film 57 are equal to each other. For example, when the stopper layer ST is located close to the barrier layer BR, the stopper layer ST is likely to break at the same timing as that of the barrier layer BR. Further, for example, when the stopper layer ST is located close to a scanning line 1 and a signal line 2, the scanning line 1 and signal line 2 are likely to break at the same timing as the stopper layer ST. Therefore, when the stopper layer ST is located in the center of the total sum of the thicknesses of the insulating films 56 and 57, the above-descried risk can be reduced.

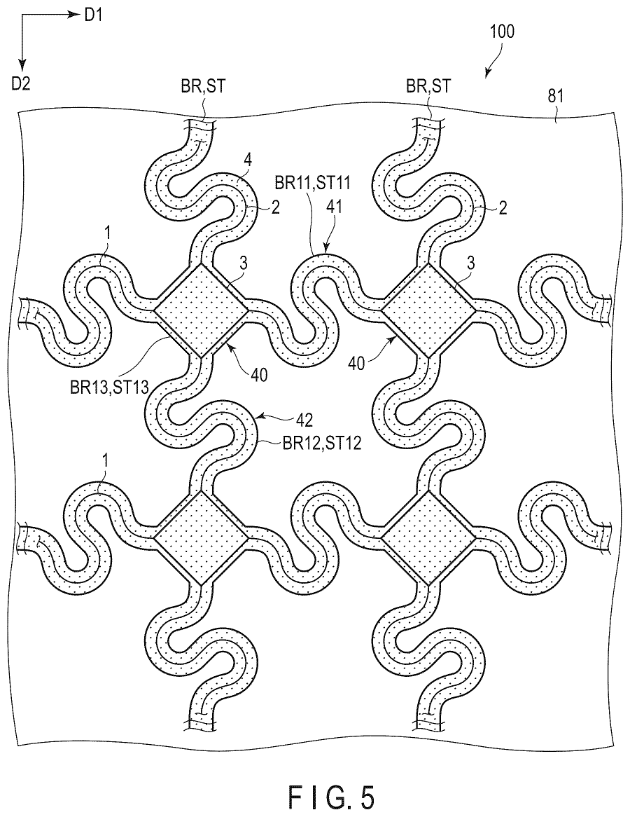

FIG. 5 is a plan view showing the barrier layer BR and the stopper layer ST. In FIG. 5, the barrier layer BR and the stopper layer ST are located in the region indicated by the dotted hatching.

The barrier layer BR includes a plurality of strip-shaped first portions BR11 extending approximately along the first direction D1 and aligned along the second direction D2, a plurality of strip-shaped second portions BR12 extending approximately along the second direction D2 and aligned along the first direction D1, and third portions BR13 each located at the intersection of a respective one of the first portion BR11 and a respective one of the second portions BR12. The first portions BR11 extend while overlapping the first strip portions 41, respectively. The second portions BR12 extend while overlapping the second strip portions 42, respectively. The first portions BR11 and the second portions BR12 are each formed into a wavy pattern in plan view. The plurality of third portions BR13 each overlap the respective one of the island-shaped portions 40. The third portions BR13 are arranged to be spaced apart from each other in a matrix along the first direction D1 and the second direction D2.

The stopper layer ST includes a plurality of strip-shaped first portions ST11 extending approximately along the first direction D1 and aligned along the second direction D2, a plurality of strip-shaped second portions ST12 extending approximately along the second direction D2 and aligned along the first direction D1, and third portions ST13 each located at the intersection of a respective one of the first portions ST11 and a respective one of the second portion ST12. The first portions ST11 extend while overlapping the first strip portions 41, respectively. The second portions ST12 extend while overlapping the second strip portions 42, respectively. The first portions ST11 and the second portions ST12 are each formed in a wavy pattern in plan view. The plurality of third portions ST13 each overlap the respective one of the island-shaped portions 40. The third portions ST13 are arranged to be spaced apart from each other in a matrix along the first direction D1 and the second direction D2.

The barrier layer BR and the stopper layer ST are located in the same region. In other words, the first portions BR11 and the first portions ST11 overlap each other, respectively. The second portions BR12 and the second portions ST12 overlap each other, respectively. The third portions BR13 and the third portions ST13 overlap each other, respectively.

Further, the first portions BR11 and the first portions ST11 overlap the scanning lines 1, respectively. The second portions BR12 and the second portions ST12 overlap the signal lines 2, respectively. The third portions BR13 and the third portions ST13 overlap the electrical elements 3, respectively.

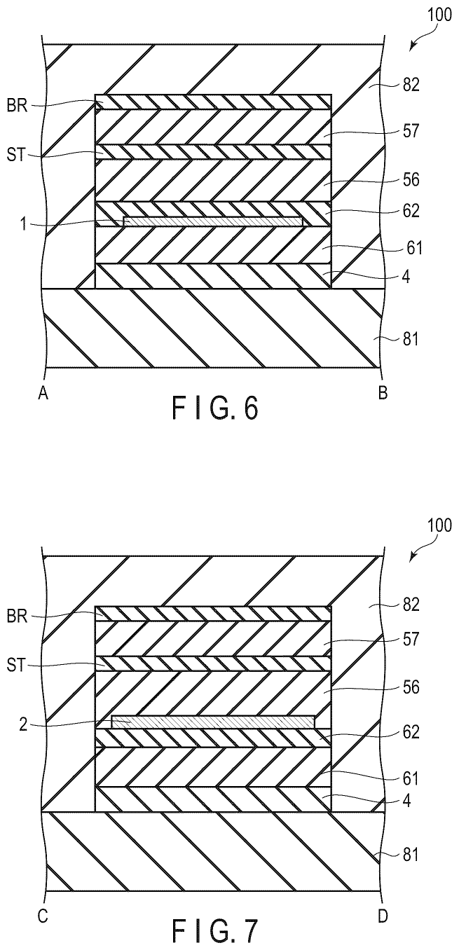

Next, with reference to FIGS. 6 and 7, the configuration of a modified example of the first embodiment will be described.

FIG. 6 is a cross-sectional view of the flexible substrate 100 taken along the line A-B shown in FIG. 2. The configuration shown in FIG. 6 is different from the configuration shown in FIG. 3 in that the flexible substrate 100 comprises insulating films 61 and 62 in place of the insulating films 51 to 55.

The insulating film 61 is located on the insulating substrate 4. The scanning lines 1 are located on the insulating film 61. The insulating film 62 is located on the insulating film 61 so as to cover the scanning lines 1. The insulating film 56 is located on the insulating film 62.

The insulating films 61 and 62 are, for example, organic insulating films each formed by an organic insulating material such as acrylic resin.

FIG. 7 is a cross-sectional view of the flexible substrate 100 taken along the line C-D shown in FIG. 2. The configuration shown in FIG. 7 is different from the configuration shown in FIG. 4 in that the flexible substrate 100 comprises insulating films 61 and 62 in place of the insulating films 51 to 55.

The insulating film 61 is located on the insulating substrate 4. The insulating film 62 is located on the insulating film 61. The signal lines 2 are located on the insulating film 62. The insulating film 56 is located on the insulating film 62 so as to cover the signal lines 2.

In such a modified example, advantageous effects similar to those of the first embodiment can be obtained.

### Second Embodiment

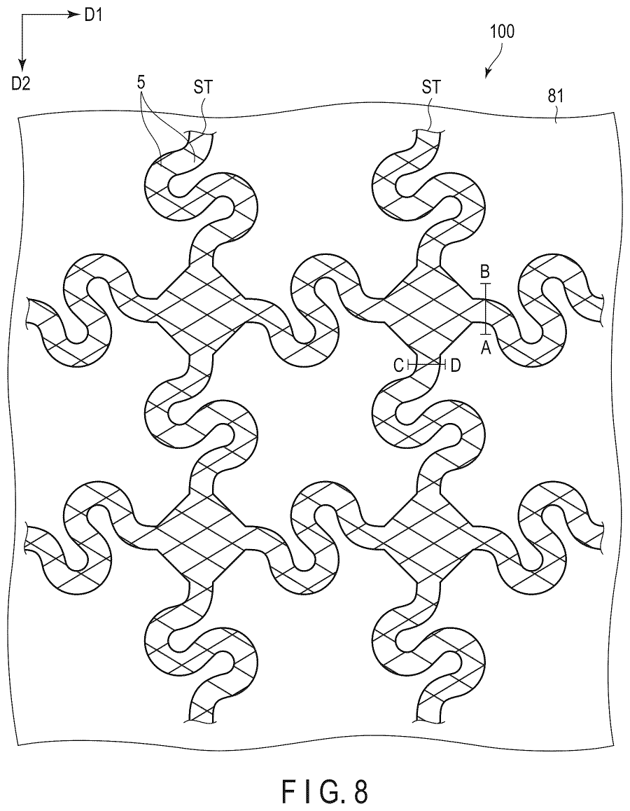

Next, a configuration of the second embodiment will be described with reference to FIGS. 8 to 10. The second embodiment is different from the first embodiment in that the stopper layer ST has slits 5.

FIG. 8 is a plan view showing the stopper layer ST.

The stopper layer ST has a plurality of slits 5. In the example illustrated, the slits 5 are each formed to be linear in plan view. The width of the slits 5 along a direction orthogonal to the direction of extension is, for example, 3 μm or more. The pattern of each slit 5 may be regularly repeated in every certain region or may be irregular. For example, the slits 5 each penetrate from an outer edge of the stopper layer ST to another outer edge in plan view. Note that the shape of the slits 5 is not limited to that of the example shown in the figure, but may be in a curved fashion or the like.

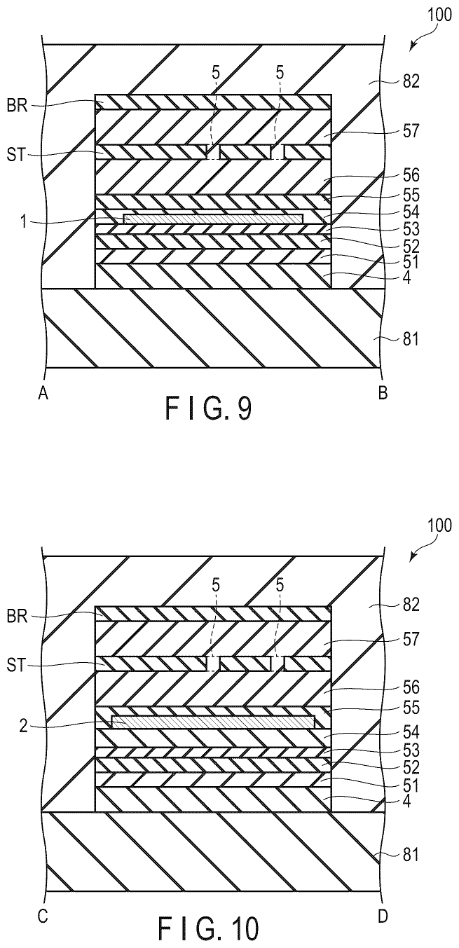

FIG. 9 is a cross-sectional view of the flexible substrate 100 taken along the line A-B shown in FIG. 8. The configuration shown in FIG. 9 is different from the configuration shown in FIG. 3 in that the stopper layer ST has slits 5.

The slits 5 each penetrate the stopper layer ST from the insulating film 56 to the insulating film 57.

FIG. 10 is a cross-sectional view of the flexible substrate 100 taken along the line C-D shown in FIG. 8. The configuration shown in FIG. 10 is different from the configuration shown in FIG. 4 in that the stopper layer ST has slits 5.

The slits 5 each penetrate the stopper layer ST from the insulating film 56 to the insulating film 57.

According to the second embodiment, the stopper layer ST has the slits 5. With this configuration, even if a crack occurs in the barrier layer BR and progresses to the stopper layer ST, the stress can be dispersed in a direction parallel to the D1-D2 plane by the slits 5. Thus, the crack can be suppressed from progressing to the layers located lower than the stopper layer ST.

In this second embodiment as well, advantageous effects similar to those of the first embodiment can be obtained.

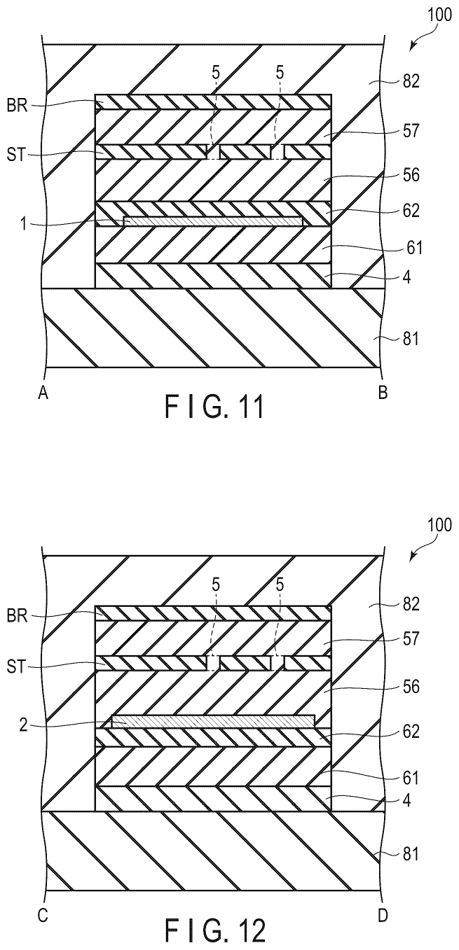

Next, with reference to FIGS. 11 and 12, the configuration of the first modified example of the second embodiment will be described.

FIG. 11 is a cross-sectional view of the flexible substrate 100 taken along the line A-B shown in FIG. 8. The configuration shown in FIG. 11 is different from the configuration shown in FIG. 6 in that the stopper layer ST has slits 5. The configuration shown in FIG. 11 is different from the configuration shown in FIG. 9 in that the flexible substrate 100 comprises insulating films 61 and 62 in place of the insulating films 51 to 55.

The slits 5 each penetrate the stopper layer ST from the insulating film 56 to the insulating film 57.

FIG. 12 is a cross-sectional view of the flexible substrate 100 taken along the line C-D shown in FIG. 8. The configuration shown in FIG. 12 is different from the configuration shown in FIG. 7 in that the stopper layer ST has slits 5. The configuration shown in FIG. 12 is different from the configuration shown in FIG. 10 in that the flexible substrate 100 comprises insulating films 61 and 62 in place of the insulating films 51 to 55.

The slits 5 each penetrate the stopper layer ST from the insulating film 56 to the insulating film 57.

In this first modified example as well, advantageous effects similar to those of the second embodiment can be obtained.

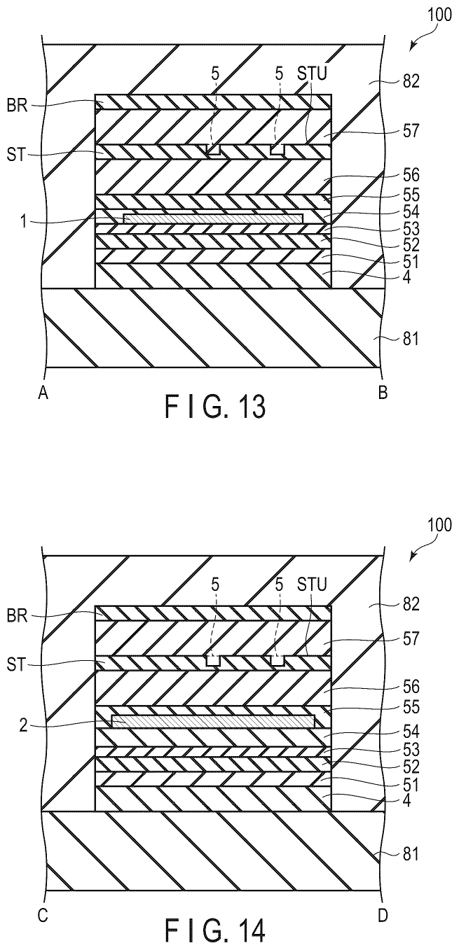

Next, with reference to FIGS. 13 and 14, a configuration of the second modified example of the second embodiment will be described.

FIG. 13 is a cross-sectional view of the flexible substrate 100 taken along the line A-B line in FIG. 8. The configuration shown in FIG. 13 is different from the configuration shown in FIG. 9 in that the slits 5 do not penetrate the stopper layer ST.

The slits 5 are formed in an upper surface STU of the stopper layer ST. The stopper layer ST is interposed between the slits 5 and the insulating film 56.

FIG. 14 is a cross-sectional view of the flexible substrate 100 taken along the line C-D shown in FIG. 8. The configuration shown in FIG. 14 is different from the configuration shown in FIG. 10 in that the slits 5 do not penetrate the stopper layer ST.

The slits 5 are formed in the upper surface STU of the stopper layer ST. The stopper layer ST is interposed between the slits 5 and the insulating film 56.

In the second modified example as well, advantageous effects similar to those of the second embodiment can be obtained.

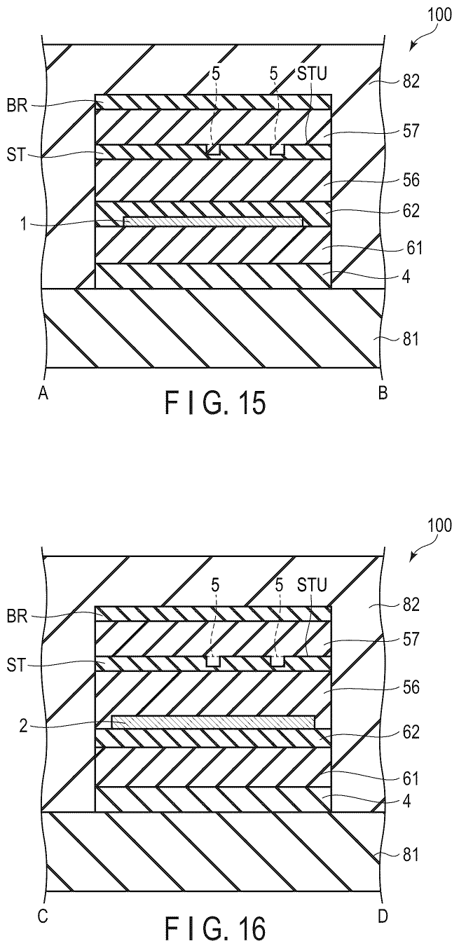

Next, with reference to FIGS. 15 and 16, a configuration of the third modified example of the second embodiment will be described.

FIG. 15 is a cross-sectional view of the flexible substrate 100 taken along the line A-B shown in FIG. 8. The configuration shown in FIG. 15 is different from the configuration shown in FIG. 11 in that the slits 5 do not penetrate the stopper layer ST. Further, the configuration shown in FIG. 15 is different from the configuration shown in FIG. 13 in that the flexible substrate 100 comprises insulating films 61 and 62 in place of the insulating films 51 to 55. The slit 5 is formed in the upper surface STU of the stopper layer ST. The stopper layer ST is interposed between the slits 5 and the insulating film 56.

FIG. 16 is a cross-sectional view of the flexible substrate 100 taken along the line C-D shown in FIG. 8. The configuration shown in FIG. 16 is different from the configuration shown in FIG. 12 in that the slits 5 do not penetrate the stopper layer ST. Further, the configuration shown in FIG. 16 is different from the configuration shown in FIG. 14 in that the flexible substrate 100 comprises insulating films 61 and 62 in place of the insulating films 51 to 55.

The slits 5 are formed in the upper surface STU of the stopper layer ST. The stopper layer ST is interposed between the slits 5 and the insulating film 56.

In this third modified example as well, advantageous effects similar to those of the second embodiment can be obtained.

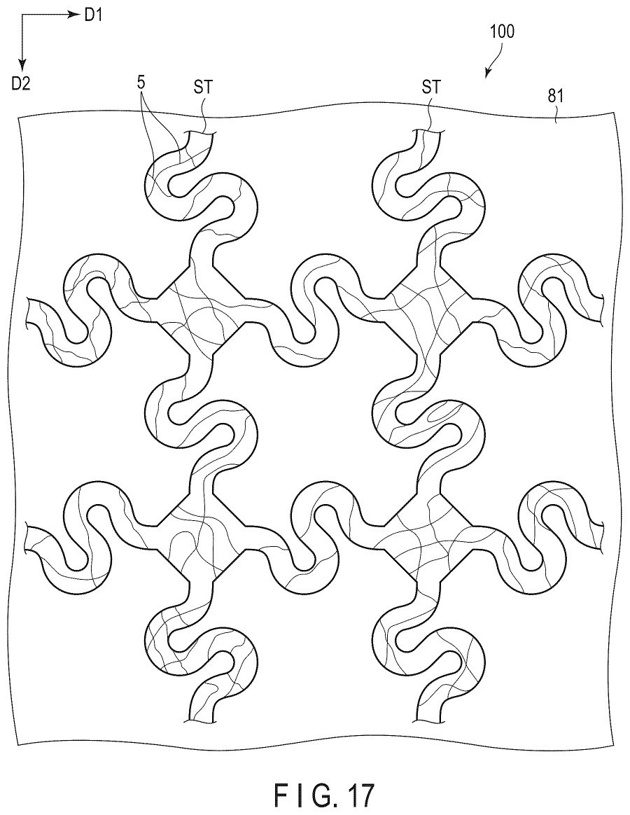

Next, with reference to FIG. 17, a configuration of the fourth modified example of the second embodiment will be described.

FIG. 17 is a plan view showing the stopper layer ST. The configuration shown in FIG. 17 is different from the configuration shown in FIG. 8 in the shape of the plurality of slits 5 of the stopper layer ST.

In the example shown in the figure, the slits 5 are curved in plan view. The pattern of the slits 5 may be regularly repeated every certain region or may be irregular. Further, for example, the slits 5 penetrate from an outer edge of the stopper layer ST to another outer edge in plan view.

Note that in the example shown in FIG. 17 as well, a configuration similar to that shown in each of the cross-sectional views shown in FIGS. 9 to 16 can be applied.

In this fourth modified example as well, advantageous effects similar to those of the second embodiment can be obtained.

As described above, according to this embodiment, a flexible substrate that can reduce the risk of breakage of wiling lines can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A flexible substrate comprising:
an insulating base including a plurality of first strip portions extending along a first direction and aligned along a second direction intersecting the first direction, a plurality of second strip portions extending along the second direction and aligned along the first direction, and a plurality of island-shaped portions each located at an intersection between a respective one of the first strip portions and a respective one of the second strip portions;
a plurality of electrical elements overlapping the island-shaped portions, respectively;
a plurality of scanning lines extending while overlapping the first strip portions, respectively;
a plurality of signal lines extending while overlapping the second strip portions, respectively;
a first organic insulating film located on a layer above the scanning lines and the signal lines and overlapping the first strip portions and the second strip portions;
a second organic insulating film located on the first organic insulating film;
a stopper layer located between the first organic insulating film and the second organic insulating film; and
a barrier layer located on the second organic insulating film.

2. The flexible substrate of claim 1, wherein
a first film thickness of the first organic insulating film and a second film thickness of the second organic insulating film are equal to each other.

3. The flexible substrate of claim 1, wherein
a rigidity of the stopper layer is equal to or less than a rigidity of the barrier layer.

4. The flexible substrate of claim 3, wherein
the stopper layer is formed from a material identical to that of the barrier layer, and
a third film thickness of the stopper layer is equal to or less than a fourth film thickness of the barrier layer.

5. The flexible substrate of claim 1, wherein
the stopper layer is formed from any one of silicon oxide, silicon nitride, polysilicon, aluminum, titanium, and copper.

6. The flexible substrate of claim 1, wherein
the stopper layer has a slit.

7. The flexible substrate of claim 6, wherein
the slit is linear in plan view.

8. The flexible substrate of claim 6, wherein
the slit is curved in plan view.

9. The flexible substrate of claim 6, wherein
the slit penetrates the stopper layer.

10. The flexible substrate of claim 6, wherein
the slit does not penetrate the stopper layer.

11. The flexible substrate of claim 1, wherein
the stopper layer includes a plurality of strip- shaped first portions extending along the first direction and aligned along the second direction and a plurality of strip-shaped second portions extending along the second direction and aligned along the first direction,
the first portions extend while overlapping the first strip portions, respectively, and
the second portions extend while overlapping the second strip portions, respectively.

12. The flexible substrate of claim 11, wherein
the first strip portions and the second strip portions are each formed in a wavy shape.
